(19) United States
(12) Patent Application Publication
(10) Pub. No.: US 2008/0236492 A1
(43) Pub. Date: Oct. 2, 2008

(54) PLASMA PROCESSING APPARATUS

(75) Inventor: Yohei YAMAZAWA, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/055,799

(22) Filed: Mar. 26, 2008

Related U.S. Application Data
(60) Provisional application No. 60/940,091, filed on May 25, 2007.

(30) Foreign Application Priority Data
Mar. 27, 2007 (JP) 2007-081193

(51) Int. Cl. C23C 16/505

(52) U.S. Cl. 118/723 I

(57) ABSTRACT

In a plasma processing apparatus comprising an evacuable processing chamber, a first electrode disposed in the processing chamber via an insulating body and a second electrode disposed in the processing chamber to face the first electrode, a central conductor and a peripheral conductor are embedded in a main surface of the first electrode via an insulating material while being separately disposed at an electrode central portion and an electrode peripheral portion, respectively. A first radio frequency leaking unit leaks a first radio frequency power applied to the first electrode from a first radio frequency power supply through at least one of the central conductor and the peripheral conductor by a desired current amount.

### FIELD OF THE INVENTION

The present invention relates to a technology for performing a plasma process on a target substrate; and, more particularly, a capacitively coupled plasma processing apparatus which applies a radio frequency power to an electrode to generate a plasma.

### BACKGROUND OF THE INVENTION

In a manufacturing process of a semiconductor device or flat panel display (FPD), a plasma is frequently used to obtain a good reaction of a processing gas at a relatively low temperature in an etching, deposition, oxidation, or sputtering process or the like. Conventionally, a capacitively coupled plasma processing apparatus capable of easily realizing a large-diameter plasma has been widely employed as a single-wafer plasma processing apparatus, especially, a plasma etching apparatus.

Generally, in the capacitively coupled plasma processing apparatus, an upper electrode and a lower electrode are disposed to face each other in parallel in a vacuum processing chamber, and a target substrate (a semiconductor wafer, a glass substrate or the like) is mounted on the lower electrode. Then, a radio frequency voltage is applied to either one of the upper and lower electrodes. Electrons are accelerated by an electric field formed between the electrodes by the radio frequency voltage to collide with a processing gas. A plasma is generated due to ionization by collision between the electrons and the processing gas, and a desired microprocessing (for example, etching) is performed on the surface of the substrate by radicals or ions in the plasma. In this case, the electrode to which the radio frequency voltage is applied is connected to a radio frequency power supply via a blocking capacitor in a matching unit and thus serves as a cathode. In a cathode coupling method, in which a radio frequency voltage is applied to the lower electrode for supporting the substrate and the lower electrode serves as a cathode, the ions in the plasma are substantially vertically accelerated toward the substrate by a self-bias voltage generated in the lower electrode, thereby enabling an anisotropic etching. See, for example, Japanese Patent Laid-open Publication No. 2001-313286

It is required to maintain a minimum difference between process characteristics in a central portion and a peripheral (edge) portion of the substrate in order to improve the production yield of a single-wafer plasma process. However, in the capacitively coupled plasma processing apparatus, a plasma density distribution tends to be nonuniform radially along with the trend of a large-diameter substrate and plasma. Generally, the plasma density tends to be relatively high in the central portion of the substrate, and relatively low in the peripheral portion of the substrate. The nonuniformity of the plasma density causes a difference in process characteristics, thereby reducing the production yield. Accordingly, it is required to obtain a uniform plasma density distribution and to control the plasma density distribution as desired.

As a conventional method for controlling the plasma density distribution, there is a method for controlling the plasma density distribution by changing an electrode gap, a magnetic field intensity distribution, an electrode impedance or the like in a radial direction of the electrode. However, the conventional method has a disadvantage that an additional mechanism (an electrode structure, a magnetic field application unit or the like) is necessary and a problem such as a low degree of freedom of control.

### SUMMARY OF THE INVENTION

The present invention provides a plasma processing apparatus capable of improving a degree of freedom of plasma density distribution control without alteration of an electrode structure or addition of a large-sized external unit such as a magnetic field unit.

In accordance with one aspect of the present invention, there is provided a plasma processing apparatus comprising: an evacuable processing chamber; a first electrode disposed in the processing chamber and mounted to the processing chamber via an insulating body; a second electrode disposed in the processing chamber to face the first electrode; a processing gas supply unit for supplying a desired processing gas to a processing space between the first electrode and the second electrode; a first radio frequency power supply for applying a first radio frequency power to the first electrode; a central conductor and a peripheral conductor (surrounding conductor) which are embedded in a main surface of the first electrode via an insulating material and are separately disposed at an electrode central portion and an electrode peripheral portion, respectively; and a first radio frequency leaking unit for leaking the first radio frequency power applied to the first electrode from the first radio frequency power supply to an earth ground through at least one of the central conductor and the peripheral conductor by a desired current amount.

In the configuration of the plasma processing apparatus, the first radio frequency leaking unit leaks a part of the first radio frequency power applied to the first electrode from the first radio frequency power supply through the central conductor and/or the peripheral conductor without discharging it to the processing space. Accordingly, it is possible to reduce the radio frequency current discharged to the processing space from a region of the conductor in which the radio frequency leakage current flows, and to decrease the plasma density in the corresponding region. As the current amount of the radio frequency leakage current increases, the reduced amount of the radio frequency current increases and the reduction rate of the plasma density increases. Consequently, it is possible to control the distribution of the radio frequency current discharged to the processing space from the main surface of the first electrode by locally leaking a desired amount of the radio frequency current from the main surface of the first electrode through the central conductor and/or the peripheral conductor. Resultantly, it is possible to control the plasma density distribution characteristics as desired.

Preferably, the first radio frequency leaking unit comprises a transmission line connected to the central conductor or the peripheral conductor and an impedance adjusting unit which provides a desired impedance to the first radio frequency power in the transmission line. In this case, the impedance adjusting unit preferably comprises a variable impedance circuit provided in the transmission line. Accordingly, it is possible to variably control the current amount of the radio frequency leakage current as desired by variably controlling the impedance. Further, the impedance adjusting unit comprises a radio frequency current measuring unit which measures a current amount of the first radio frequency power flowing in the transmission line, and an impedance controller which variably controls an impedance of the impedance circuit such that the current amount of the first radio frequency power flowing in the transmission line is equal to a desired value. With such configuration, it is possible to accurately control the current amount of the radio frequency leakage current to a desired value by the feedback control.

Preferably, the first radio frequency leaking unit comprises a central transmission line connected to the central conductor, a central impedance adjusting unit which provides a desired impedance to the first radio frequency power in the central transmission line, a peripheral transmission line connected to the peripheral conductor, and a peripheral impedance adjusting unit which provides a desired impedance to the first radio frequency power in the peripheral transmission line. In this case, preferably, the central impedance adjusting unit comprises a central variable impedance circuit provided in the central transmission line, and the peripheral impedance adjusting unit comprises a peripheral variable impedance circuit provided in the peripheral transmission line. More preferably, the central impedance adjusting unit comprises a central radio frequency current measuring unit which measures a current amount of the first radio frequency power flowing in the central transmission line, and a central impedance controller which variably controls an impedance of the central impedance circuit such that the current amount of the first radio frequency power flowing in the central transmission line is equal to a desired value. Further, the peripheral impedance adjusting unit comprises a peripheral radio frequency current measuring unit which measures a current amount of the first radio frequency power flowing in the peripheral transmission line, and a peripheral impedance controller which variably controls an impedance of the peripheral impedance circuit such that the current amount of the first radio frequency power flowing in the peripheral transmission line is equal to a desired value.

With such configurations, it is possible to flexibly or precisely control the plasma density distribution characteristics by independently controlling the current amount of the radio frequency leakage current at the respective regions of the central conductor and the peripheral conductor.

The present invention may be also applied to a dual frequency application type apparatus in which two radio frequency powers having different frequencies are dually applied to the same radio frequency electrode. That is, preferably, the plasma processing apparatus further comprises a second radio frequency power supply for applying a second radio frequency power of a frequency different from that of the first radio frequency power to the first electrode, and a second radio frequency leaking unit which leaks the second radio frequency power applied to the first electrode from the second radio frequency power supply through at least one of the central conductor and the peripheral conductor by a desired current amount. In this case, the first radio frequency power may have a frequency appropriate for generating a plasma of the processing gas in the processing space, and the first radio frequency leaking unit may leak the first radio frequency power to control plasma density distribution characteristics in a radial direction of the first electrode. Further, the second radio frequency power may have a frequency appropriate for controlling a self-bias voltage generated in the first electrode, and the second radio frequency leaking unit may leak the second radio frequency power to control self-bias voltage characteristics in the radial direction of the first electrode.

In the above-mentioned dual frequency application type apparatus, preferably, the first radio frequency leaking unit comprises a first transmission line connected to the central conductor or the peripheral conductor, and a first impedance adjusting unit which provides a desired impedance to the first radio frequency power in the first transmission line. In this case, the first impedance adjusting unit may comprise a first variable impedance circuit provided in the first transmission line and, preferably, the first impedance adjusting unit may comprise a first radio frequency current measuring unit which measures a current amount of the first radio frequency power flowing in the first transmission line, and a first impedance controller which variably controls an impedance of the first impedance circuit such that the current amount of the first radio frequency power flowing in the first transmission line is equal to a desired value.

Furthermore, the second radio frequency leaking unit may comprise a second transmission line connected to the central conductor or the peripheral conductor, and a second impedance adjusting unit which provides a desired impedance to the second radio frequency power in the second transmission line. In this case, the second impedance adjusting unit may comprise a second variable impedance circuit provided in the second transmission line and, preferably, the second impedance adjusting unit may comprise a second radio frequency current measuring unit which measures a current amount of the second radio frequency power flowing in the second transmission line, and a second impedance controller which variably controls an impedance of the second impedance circuit such that the current amount of the second radio frequency power flowing in the second transmission line is equal to a desired value.

Preferably, the first radio frequency leaking unit comprises a first transmission line connected to the central conductor or the peripheral conductor, and a first impedance adjusting unit which provides a desired impedance to the first radio frequency power in the first transmission line, and the second radio frequency leaking unit comprises a second transmission line connected to the central conductor or the peripheral conductor, and a second impedance adjusting unit which provides a desired impedance to the second radio frequency power in the second transmission line.

In this case, the first impedance adjusting unit may comprise a first variable impedance circuit provided in the first transmission line, and the second impedance adjusting unit may comprise a second variable impedance circuit provided in the second transmission line.

More preferably, the first impedance adjusting unit may comprise a first radio frequency current measuring unit which measures a current amount of the first radio frequency power flowing in the first transmission line, and a first impedance controller which variably controls an impedance of the first impedance circuit such that the current amount of the first radio frequency power flowing in the first transmission line is equal to a desired value, and the second impedance adjusting unit comprises a second radio frequency current measuring unit which measures a current amount of the second radio frequency power flowing in the second transmission line, and a second impedance controller which variably controls an impedance of the second impedance circuit such that the current amount of the second radio frequency power flowing in the second transmission line is equal to a desired value.

In this case, the first transmission line and the second transmission line may be the same transmission line.

Alternatively, the first radio frequency leaking unit comprises a first central impedance adjusting unit which provides a desired impedance to the first radio frequency power in a central transmission line connected to the central conductor, and a first peripheral impedance adjusting unit which provides a desired impedance to the first radio frequency power in a peripheral transmission line connected to the peripheral conductor, and the second radio frequency leaking unit comprises a second central impedance adjusting unit which provides a desired impedance to the second radio frequency power in the central transmission line, and a second peripheral impedance adjusting unit which provides a desired impedance to the second radio frequency power in the peripheral transmission line.

Preferably, the first central impedance adjusting unit comprises a first central variable impedance circuit provided in the central transmission line, and the first peripheral impedance adjusting unit comprises a first peripheral variable impedance circuit provided in the peripheral transmission line, and the second central impedance adjusting unit comprises a second central variable impedance circuit provided in the central transmission line, and the second peripheral impedance adjusting unit comprises a second peripheral variable impedance circuit provided in the peripheral transmission line. In this case, more preferably, the first central impedance adjusting unit comprises a first central radio frequency current measuring unit which measures a current amount of the first radio frequency power flowing in the central transmission line and a first central impedance controller which variably controls an impedance of the first central impedance circuit such that the current amount of the first radio frequency power flowing in the central transmission line is equal to a desired value. The first peripheral impedance adjusting unit comprises a first peripheral radio frequency current measuring unit which measures a current amount of the first radio frequency power flowing in the peripheral transmission line and a first peripheral impedance controller which variably controls an impedance of the first peripheral impedance circuit such that the current amount of the first radio frequency power flowing in the peripheral transmission line is equal to a desired value. The second central impedance adjusting unit comprises a second central radio frequency current measuring unit which measures a current amount of the second radio frequency power flowing in the central transmission line and a second central impedance controller which variably controls an impedance of the second central impedance circuit such that the current amount of the second radio frequency power flowing in the central transmission line is equal to a desired value. The second peripheral impedance adjusting unit comprises a second peripheral radio frequency current measuring unit which measures a current amount of the second radio frequency power flowing in the peripheral transmission line and a second peripheral impedance controller which variably controls an impedance of the second peripheral impedance circuit such that the current amount of the second radio frequency power flowing in the peripheral transmission line is equal to a desired value.

In accordance with another aspect of the present invention, there is provided A plasma processing apparatus, comprising: an evacuable processing chamber; a first electrode disposed in the processing chamber via an insulating body; a second electrode disposed in the processing chamber to face the first electrode via an insulating body; a processing gas supply unit for supplying a desired processing gas to a processing space between the first electrode and the second electrode; a first radio frequency power supply for applying a first radio frequency power to the first electrode; a second radio frequency power supply for applying a second radio frequency power of a frequency different from that of the first radio frequency power to the second electrode; a central conductor and a peripheral conductor (surrounding conductor) which are provided in a main surface of the first electrode via an insulating material and are separately disposed at an electrode central portion and an electrode peripheral portion, respectively; and a radio frequency attracting unit for attracting the second radio frequency power applied to the second electrode from the second radio frequency power supply through at least one of the central conductor and the peripheral conductor by a desired current amount.

With such configurations of the plasma processing apparatus, the radio frequency attracting unit locally attracts the electron current of the second radio frequency power, which is discharged to the processing space from the second electrode, through the central conductor and/or the peripheral conductor on the side of the first electrode. Accordingly, it is possible to increase the plasma density on the corresponding region by increasing the electron current in the corresponding attracting region. In this case, as the current amount of the radio frequency attraction current increases, the increased amount of the radio frequency electron current increases in the corresponding region and the increased rate of the plasma density increases. Consequently, it is possible to control the distribution of the radio frequency current discharged to the processing space from the main surface of the second electrode by locally attracting a desired amount of the radio frequency current on the main surface of the first electrode through the central conductor and/or the peripheral conductor. Resultantly, it is possible to control the plasma density distribution characteristics as desired.

Preferably, the radio frequency attracting unit comprises a transmission line connected to the central conductor or the peripheral conductor and an impedance adjusting unit which provides a desired impedance to the second radio frequency power in the transmission line. In this case, the impedance adjusting unit comprises a variable impedance circuit provided in the transmission line, a radio frequency current measuring unit which measures a current amount of the second radio frequency power flowing in the transmission line, and an impedance controller which variably controls an impedance of the impedance circuit such that the current amount of the second radio frequency power flowing in the transmission line is equal to a desired value. More preferably, the radio frequency attracting unit comprises a central transmission line connected to the central conductor, a central impedance adjusting unit which provides a desired impedance to the second radio frequency power in the central transmission line, a peripheral transmission line connected to the peripheral conductor, and a peripheral impedance adjusting unit which provides a desired impedance to the second radio frequency power in the peripheral transmission line.

In this case, preferably, the central impedance adjusting unit comprises a central variable impedance circuit provided in the central transmission line, a central radio frequency current measuring unit which measures a current amount of the second radio frequency power flowing in the central transmission line, and a central impedance controller which variably controls an impedance of the central impedance circuit such that the current amount of the second radio frequency power flowing in the central transmission line is equal to a desired value. More preferably, the peripheral impedance adjusting unit comprises a peripheral variable impedance circuit provided in the peripheral transmission line, a peripheral radio frequency current measuring unit which measures a current amount of the second radio frequency power flowing in the peripheral transmission line, and a peripheral impedance controller which variably controls an impedance of the peripheral impedance circuit such that the current amount of the second radio frequency power flowing in the peripheral transmission line is equal to a desired value.

The plasma processing apparatus further comprises a radio frequency leaking unit for leaking the first radio frequency power applied to the first electrode from the first radio frequency power supply to an earth ground through at least one of the central conductor and the peripheral conductor by a desired current amount. In this case, the second radio frequency power has a frequency appropriate for generating a plasma of the processing gas in the processing space, and the radio frequency attracting unit attracts the second radio frequency power to control plasma density distribution characteristics in a radial direction of the first electrode. Further, the first radio frequency power has a frequency appropriate for controlling a self-bias voltage generated in the first electrode, and the radio frequency leaking unit leaks the first radio frequency power to control self-bias voltage characteristics in the radial direction of the first electrode. Furthermore, the radio frequency attracting unit comprises a first transmission line connected to the central conductor or the peripheral conductor, and a first impedance adjusting unit which provides a desired impedance in the first transmission line, and the radio frequency leaking unit comprises a second transmission line connected to the central conductor or the peripheral conductor, and a second impedance adjusting unit which provides a desired impedance in the second transmission line.

In this case, the first impedance adjusting unit preferably comprises a first variable impedance circuit provided in the first transmission line and, more preferably, a first radio frequency current measuring unit which measures a current amount of the second radio frequency power flowing in the first transmission line, and a first impedance controller which variably controls an impedance of the first impedance circuit such that a current amount of the first radio frequency power flowing in the first transmission line is equal to a desired value. Furthermore, the second impedance adjusting unit preferably comprises a second radio frequency current measuring unit which measures the current amount of the first radio frequency power flowing in the second transmission line, and a second impedance controller which variably controls an impedance of the second impedance circuit such that the current amount of the second radio frequency power flowing in the second transmission line is equal to a desired value.

In this case, the first transmission line and the second transmission line may be the same transmission line.

Alternatively, the radio frequency attracting unit may comprise a first central impedance adjusting unit which provides a desired impedance to the second radio frequency power in a central transmission line connected to the central conductor, and a first peripheral impedance adjusting unit which provides a desired impedance to the second radio frequency power in a peripheral transmission line connected to the peripheral conductor, and the radio frequency leaking unit may comprise a second central impedance adjusting unit which provides a desired impedance to the first radio frequency power in the central transmission line, and a second peripheral impedance adjusting unit which provides a desired impedance to the first radio frequency power in the peripheral transmission line.

In this case, preferably, the first central impedance adjusting unit comprises a first central variable impedance circuit provided in the central transmission line, and the first peripheral impedance adjusting unit comprises a first peripheral variable impedance circuit provided in the peripheral transmission line. Further, the second central impedance adjusting unit comprises a second central variable impedance circuit provided in the central transmission line, and the second peripheral impedance adjusting unit comprises a second peripheral variable impedance circuit provided in the peripheral transmission line.

More preferably, the first central impedance adjusting unit comprises a first central radio frequency current measuring unit which measures a current amount of the second radio frequency power flowing in the central transmission line and a first central impedance controller which variably controls an impedance of the first central impedance circuit such that the current amount of the second radio frequency power flowing in the central transmission line is equal to a desired value. Further, the first peripheral impedance adjusting unit comprises a first peripheral radio frequency current measuring unit which measures a current amount of the second radio frequency power flowing in the peripheral transmission line and a first peripheral impedance controller which variably controls an impedance of the first peripheral impedance circuit such that the current amount of the second radio frequency power flowing in the peripheral transmission line is equal to a desired value. The second central impedance adjusting unit comprises a second central radio frequency current measuring unit which measures a current amount of the first radio frequency power flowing in the central transmission line and a second central impedance controller which variably controls an impedance of the second central impedance circuit such that the current amount of the first radio frequency power flowing in the central transmission line is equal to a desired value. The second peripheral impedance adjusting unit comprises a second peripheral radio frequency current measuring unit which measures a current amount of the first radio frequency power flowing in the peripheral transmission line and a second peripheral impedance controller which variably controls an impedance of the second peripheral impedance circuit such that the current amount of the first radio frequency power flowing in the peripheral transmission line is equal to a desired value.

Further, in the plasma processing apparatus described above, a target substrate may be mounted on the first electrode. In this case, the plasma processing apparatus may further comprises a DC voltage applying unit for applying a DC voltage to at least one of the central conductor and the peripheral conductor to hold the substrate on the first electrode by an electrostatic attraction force. In addition, the plasma processing apparatus may further comprise a first DC voltage applying unit for applying a first DC voltage to the central conductor and a second DC voltage applying unit for applying a second DC voltage to the peripheral conductor.

Further, in order to control a temperature of the first electrode, at least one of the central conductor and the peripheral conductor may be configured to serve as a resistance heating element and the plasma processing apparatus may further comprise a heater power supply for supplying a power to the resistance heating element. Preferably, the central conductor and the peripheral conductor may be configured to serve as a first and a second resistance heating element, respectively, and the plasma processing apparatus may further comprise a first heater power supply for supplying a power to the first resistance heating element and a second heater power supply for supplying a power to the second resistance heating element.

In accordance with the plasma processing apparatus of the present invention having the above-mentioned configuration and operation, it is possible to improve a degree of freedom of plasma density distribution control without alteration of an electrode structure or addition of a large-sized external unit such as a magnetic field unit.

### BRIEF DESCRIPTION OF THE DRAWINGS

The objects and features of the present invention will become apparent from the following description of embodiments given in conjunction with the accompanying drawings, in which:

FIG. 1 illustrates a longitudinal cross sectional view showing a configuration of a plasma etching apparatus in accordance with a first embodiment of the present invention;

FIG. 2 illustrates exemplary configurations of a central and a peripheral impedance adjusting unit in accordance with the first embodiment;

FIG. 3 explains the operations of the central and the peripheral impedance adjusting unit in accordance with the first embodiment;

FIG. 4 illustrates a longitudinal cross sectional view showing a configuration of a plasma etching apparatus in accordance with a second embodiment of the present invention;

FIG. 5 explains the operations of the central and the peripheral impedance adjusting unit in accordance with the second embodiment;

FIG. 6 illustrates exemplary configurations of a central and a peripheral impedance adjusting unit in accordance with the second embodiment;

FIG. 7 illustrates a longitudinal cross sectional view showing a configuration of a plasma etching apparatus in accordance with a third embodiment of the present invention;

FIG. 8 explains the operations of the central and the peripheral impedance adjusting unit in accordance with the third embodiment; and

FIG. 9 illustrates a longitudinal cross sectional view showing a configuration of a plasma etching apparatus in accordance with a fourth embodiment of the present invention.

### DETAILED DESCRIPTION OF THE PREFERRED EMBODIMENTS

Hereinafter, embodiments of the present invention will be described with reference to the accompanying drawings.

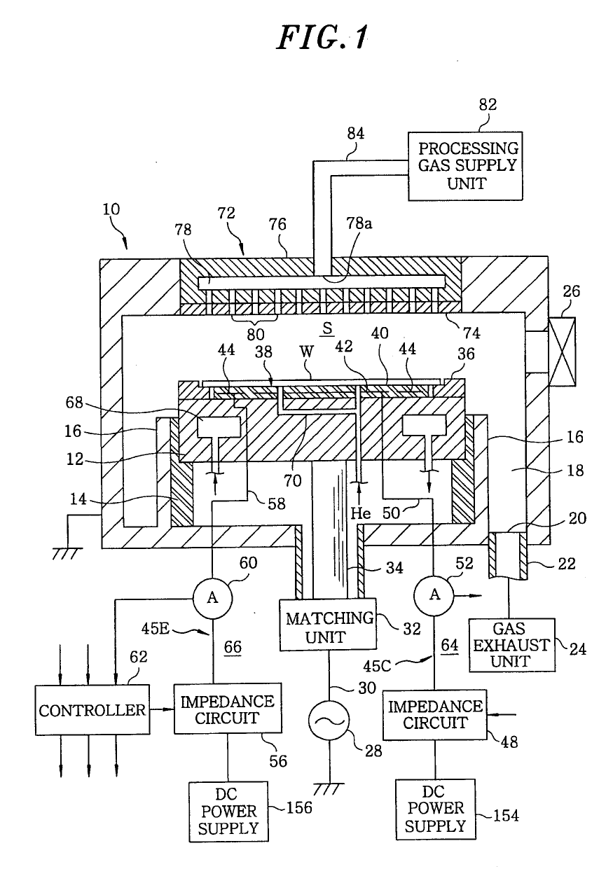

FIG. 1 illustrates a configuration of a plasma processing apparatus in accordance with a first embodiment of the present invention. The plasma processing apparatus is configured as a capacitively coupled plasma etching apparatus of a cathode coupling type. The plasma processing apparatus comprises a cylindrical chamber (processing chamber) 10 made of metal such as aluminum or stainless steel. The chamber 10 is frame grounded.

A circular plate-shaped susceptor 12 serving as a lower electrode is horizontally disposed inside the chamber 10 to mount a target substrate, e.g., a semiconductor wafer W thereon. The susceptor 12 is made of, e.g., aluminum. The susceptor 12 is supported by an insulating cylindrical support portion 14 in a non-ground state, the cylindrical support portion 14 extending vertically upward from a bottom portion of the chamber 10 and made of, for example, ceramic. A conductive cylindrical supporting portion 16 extending upward from the bottom portion of the chamber 10 is formed along an outer periphery of the cylindrical support portion 14. An annular gas exhaust passageway 18 is formed between the cylindrical supporting portion 16 and an inner wall of the chamber 10. A gas exhaust port 20 is disposed on the bottom portion of the gas exhaust passageway 18. The gas exhaust port 20 is connected to a gas exhaust unit 24 via a gas exhaust line 22. The gas exhaust unit 24 has a vacuum pump such as a turbo molecular pump, so that a processing space inside the chamber 10 can be depressurized to a desired vacuum level. A gate valve 66 is provided at a sidewall of the chamber 10 to open and close a loading/unloading port for the semiconductor wafer W.

A radio frequency (RF) power supply 28 is electrically connected to the susceptor 12 via an RF cable 30, a matching unit 32 and a lower power feed rod 34. The radio frequency power supply 28 outputs a radio frequency power of a specific frequency, e.g., 40 MHz, when a plasma process is performed in the chamber 10. The RF cable 30 is formed of, e.g., a coaxial cable. The matching unit 32 includes a matching circuit for matching an impedance of the radio frequency power supply 28 to an impedance of a load (mainly, electrode or plasma). Also, the matching unit 32 includes an RF sensor for automatic matching, a controller, a stepping motor and the like.

The susceptor 12 has a larger diameter than that of the semiconductor wafer W. A main surface, that is, an upper surface of the susceptor 12 is radially divided into two portions of a central portion, that is, a wafer mounting portion and an annular peripheral portion. The wafer mounting portion has substantially the same shape (circular shape) and the same size as those of the wafer W. The annular peripheral portion extends along the outside of the wafer mounting portion. The semiconductor wafer W as a processing target is mounted on the wafer mounting portion. A focus ring 36 having an inner diameter slightly larger than the diameter of the semiconductor wafer W is mounted on the annular peripheral portion. The focus ring 36 is formed of, for example, Si, SiC, C or SiO₂ according to an etching target material of the semiconductor wafer W.

A circular plate-shaped electrostatic chuck 38 is disposed on the wafer mounting portion of the upper surface of the susceptor 12. The electrostatic chuck 38 includes a film-shaped or plate-shaped dielectric member 40 which is integrally formed or fixed on the upper surface of the susceptor 12. The dielectric member 40 includes two conductors, that is, a central conductor 42 and a peripheral conductor 44, which are separately disposed radially to be embedded or buried therein. The central conductor 42 is formed of a circular plate-shaped conductor or mesh-shaped conductor having a smaller diameter than that of the semiconductor wafer W. The central conductor 42 is arranged coaxially or concentrically with the susceptor 12. Meanwhile, the peripheral conductor 44 is formed of an annular plate-shaped conductor or mesh-shaped conductor having a slightly larger inner diameter than an outer diameter of the central conductor 42. Also, the peripheral conductor 44 is arranged coaxially or concentrically with the susceptor 12. Further, an outer diameter of the peripheral conductor 44 may be smaller or larger than an outer diameter of the semiconductor wafer W, while it is preferable that the outer diameter of the peripheral conductor 44 is similar to the outer diameter of the semiconductor wafer W.

In this embodiment, the central conductor 42 and the peripheral conductor 44 have a function of discharging or leaking a radio frequency current from the susceptor 12 to an earth ground, as will be described later. Accordingly, preferably, the central conductor 42 and the peripheral conductor 44 are formed of a material and in a shape to have a large allowable current, and may be formed of, for example, a copper line having a large diameter or a thick copper plate.

An external DC power supply 46 that is disposed at the outside of the chamber 10 is electrically connected to the central conductor 42 via an impedance circuit 48 and a transmission line 50 for both DC and radio frequency power. In this case, the transmission line 50 and the impedance circuit 48 form a central transmission line 45C. A current sensor 52 is provided on the transmission line 50 to measure a radio frequency leakage current MI_{C} flowing in the transmission line. When a DC voltage is applied to the central conductor 42 from the DC power supply 46, static electricity is generated directly above the central conductor 42 between the semiconductor wafer W and the electrostatic chuck 38. Accordingly, the semiconductor wafer W can be attractively held on the electrostatic chuck 38 by a Coulomb force.

Meanwhile, an additional external DC power supply 54 is electrically connected to the peripheral conductor 44 via an impedance circuit 56 and a transmission line 58 for both DC and radio frequency power. In this case, the transmission line 58 and the impedance circuit 56 form a peripheral transmission line 45E. A current sensor 60 is provided on the transmission line 58 to measure a radio frequency leakage current MI_{E} flowing in the transmission line. When a specific DC voltage is applied to the peripheral conductor 44 from the DC power supply 54, a Coulomb force is generated directly above the peripheral conductor 44 such that the semiconductor wafer W can be attractively held on the electrostatic chuck 50. Further, both the transmission lines 50 and 58 have a function of discharging the radio frequency leakage currents MI_{C} and MI_{E} from the central conductor 42 and the peripheral conductor 44, respectively. Accordingly, the transmission lines 50 and 58 may be formed of a coated line having a large allowable current and a large diameter.

Generally, DC voltages of opposite polarities are applied to the central conductor 42 and the peripheral conductor 44. Accordingly, polarities of the DC power supplies 46 and 54 may be selected such that, for example, a positive DC voltage is applied to the central conductor 42 and a negative DC voltage is applied to the peripheral conductor 44.

The impedance circuits 48 and 56 are formed of a variable impedance circuit capable of varying an impedance with respect to the radio frequency current under control of a controller 62 and, together with the controller 62 and the current sensors 52 and 60, form a central and a peripheral impedance adjusting unit 64 and 66, respectively. The configurations and operations of both the impedance adjusting units 64 and 66 will be described later in detail.

A coolant path 68 formed in, e.g., a ring shape extending circumferentially is provided inside the susceptor 12. A coolant of a specific temperature is supplied into the coolant path 68 from an external chiller unit (not shown) through a line to flow along the coolant path 68. Accordingly, the temperature of the semiconductor wafer W on the electrostatic chuck 38 can be controlled by the temperature of the coolant. Further, in order to further improve accuracy of the temperature control of the wafer, a heat transfer gas such as He gas is supplied between the electrostatic chuck 38 and the semiconductor wafer W from a heat transfer gas supply unit (not shown) via a gas supply line and a gas passageway 70 inside the susceptor 12.

A shower head 72 also serving as an upper electrode is disposed at a ceiling portion of the chamber 10 to be directly attached to the chamber 10 (anode grounded), the shower head 72 facing the susceptor 12 in parallel. The shower head 72 includes an electrode plate 74 facing the susceptor 12 and an electrode support body 76 which supports the electrode plate 74 to detachably mount the electrode plate 74 on a rear surface thereof. A gas chamber 78 is formed inside the electrode support body 76. A plurality of gas injection openings 80 are formed in the electrode support body 76 and the electrode plate 74 to path therethrough from the gas chamber 78 toward the susceptor 12. A gap between the electrode plate 74 and the susceptor 12 is a plasma generation space or processing space S. A gas inlet port 78a is provided at an upper portion of the gas chamber 78. The gas inlet port 78a is connected to a processing gas supply unit 82 via a gas supply line 84. The electrode plate 74 is formed of, for example, Si, SiC, or C. The electrode support body 76 is made of, for example, alumite treated aluminum.

The controller 62 has, for example, a microcomputer. The controller 62 not only executes the control of the impedance adjusting units 64 and 66 as described above, but also controls each part of devices such as the radio frequency power supply 28, the gas exhaust unit 24, the DC power supplies 46 and 54 and the processing gas supply unit 82 and a whole sequence of the devices.

In order to perform an etching process in the plasma etching apparatus, first, the gate valve 26 is opened and the semiconductor wafer W to be processed is loaded into the chamber 10 and mounted on the electrostatic chuck 38. Then, an etching gas (in general, a gaseous mixture) is introduced from the processing gas supply unit 82 into the chamber 10 at a specific flow rate and a specific flow rate ratio. Then, a pressure inside the chamber 10 is adjusted to a set value by the gas exhaust unit 24. Further, the radio frequency power supply 28 is turned on to output a radio frequency power of a specific frequency (40 MHz) at a specific power level. The radio frequency power is supplied or applied to the susceptor 12 via the RF cable 30, the matching unit 32 and the lower power feed rod 34. Further, both the DC power supplies 46 and 54 are turned on to confine a heat transfer gas (He gas) at a contact boundary surface between the electrostatic chuck 38 and the semiconductor wafer W by an electrostatic adsorptive force. Further, cooling water controlled at a specific temperature is supplied into the coolant path 68 inside the susceptor 12 from the chiller unit. The etching gas injected from the shower head 72 is converted into a plasma between the electrodes 12 and 72 by a radio frequency discharge. Then, a film on the main surface of the semiconductor wafer W is etched by radicals or ions generated in the plasma.

In the plasma etching apparatus, the radio frequency power is applied to the susceptor 12 from the radio frequency power supply 28. Accordingly, a plasma of the processing gas is generated in the processing space S by a radio frequency discharge between the susceptor 12 and the upper electrode 72 and a radio frequency discharge between the susceptor 12 and the sidewall of the chamber 10. The generated plasma is diffused in all directions, especially radially outwardly of the chamber. An electron current in the plasma flows to the ground via the upper electrode 72, the sidewall of the chamber 10 or the like.

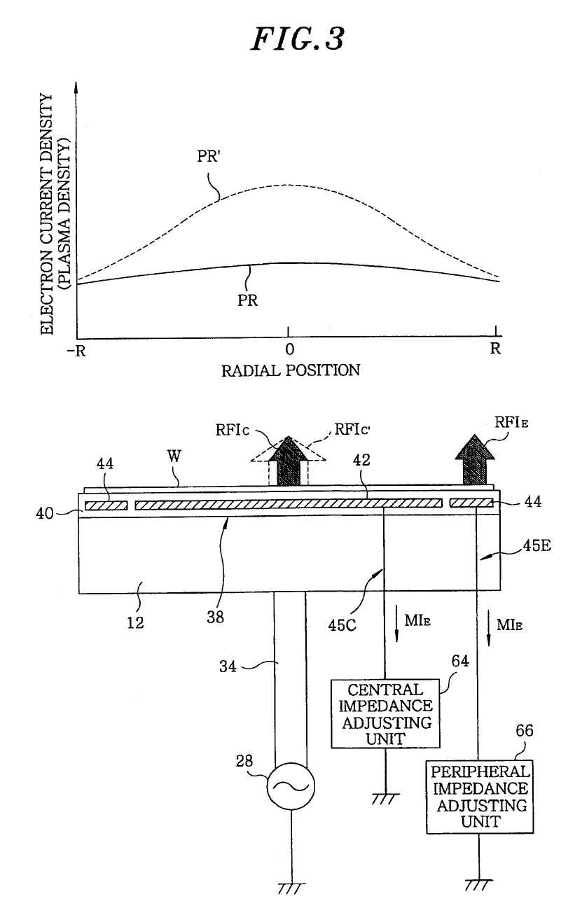

If the plasma etching apparatus does not include the impedance adjusting units 64 and 66, an RF current tends to be collected at the central portion of the susceptor 12 due to a skin effect as the frequency of the radio frequency power increases. The susceptor 12 is closer to the upper electrode 72 than the sidewall of the chamber 10, the upper electrode 34 and the sidewall of the chamber 10 having the same potential (ground potential) with respect to the susceptor 12. Accordingly, a larger amount of RF electron current is discharged from the central portion of the susceptor 12 toward the processing space S. As a result, the plasma density in the processing space S above the susceptor 12 has a mountain-shaped distribution approximately symmetric with respect to a vertical line as represented by a dotted line PR′ in FIG. 3, in which the plasma density has a maximum value around the center of the susceptor 12 and there is a significant difference in the plasma density between the central portion (position 0) and the peripheral portion (positions R and −R). Since an etching rate distribution within the surface of the wafer directly depends on the plasma density distribution, the etching rate distribution within the surface of the wafer also has a mountain-shaped distribution with a high etching rate in the central portion.

In this embodiment, a ratio or rate of RF electron currents RFI_{C} and RFI_{E}, which are respectively discharged from the central portion and the peripheral portion of the main surface of the susceptor 12 toward the processing space S, can be varied as desired by means of the central and the peripheral impedance adjusting unit 64 and 66. Accordingly, the plasma density distribution characteristics can be controlled as desired. For example, a plasma density distribution characteristic with a high plasma density in the central portion as represented by the dotted line PR′ in FIG. 3 can be rectified into a plasma density distribution characteristic with an almost uniform or flat plasma density as represented by a solid line PR. Thus, it is possible to easily realize uniformity of the etching rate distribution within the surface of the wafer.

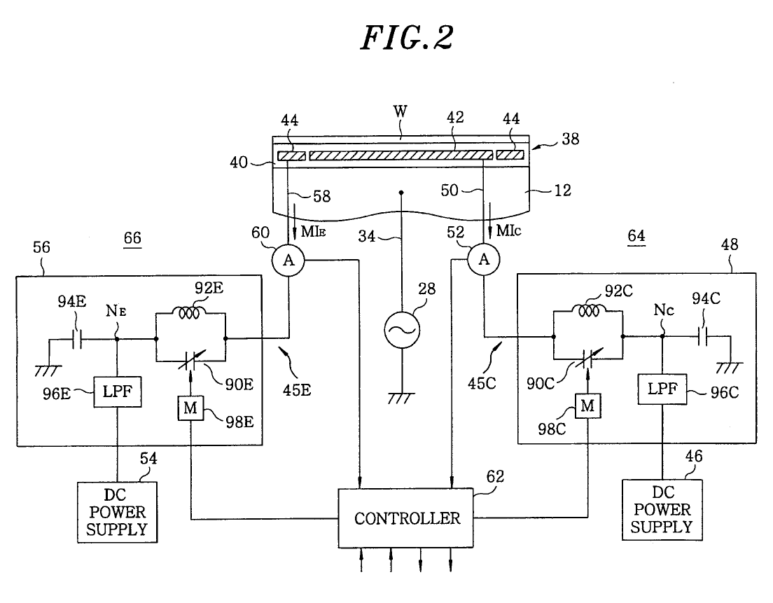

FIG. 2 illustrates exemplary configurations of the central and the peripheral impedance adjusting unit 64 and 66. The impedance circuit 48 of the central impedance adjusting unit 64 includes an LC circuit having at least one variable reactance element. In the illustrated example, a variable capacitor 90C and a coil 92C are connected in parallel to each other. The LC parallel circuit having the variable capacitor 90C and the coil 92C is connected in series to one terminal of a fixed capacitor 94C. The other terminal of the fixed capacitor 94C is connected to the ground potential. Further, a connection node N_{C} between the LC parallel circuit (the variable capacitor 90C and the coil 92C) and the fixed capacitor 94C is connected to an output terminal of the DC power supply 46 via a low pass filter (LPF) 96C. The controller 62 can variably control an impedance position of the variable capacitor 90C via a step motor 98C.

A DC voltage outputted from the DC power supply 46 flows through the LPF 96C and the coil 92C and, then, is applied to the central conductor 42 of the electrostatic chuck 38 through the transmission line 50. Meanwhile, a part of the radio frequency power, which is applied to the susceptor 12 from the radio frequency power supply 28 via the power feed rod 34, flows into the transmission line 50 from the central conductor 42 of the electrostatic chuck 38. The RF current, that is, the central RF leakage current MI_{C} flows in the transmission line 50 such that the amount of the current is inversely proportional to the impedance of the impedance circuit 48. The central RF leakage current MI_{C} flows to the ground from the LC parallel circuit (the variable capacitor 90C and the coil 92C) through the fixed capacitor 94C without flowing into the DC power supply 46. The LPF 96C almost completely blocks the central RF leakage current MI_{C} in front of the DC power supply 46. The current sensor 52 measures a current value or current amount of the central RF leakage current MI_{C} flowing in the transmission line 50. The measured value of the RF leakage current is provided to the controller 62. The controller 62 may variably control the impedance position of the variable capacitor 90C such that the measured value of the RF leakage current obtained by the current sensor 52 is equal to a set value.

The impedance circuit 56 of the peripheral impedance adjusting unit 66 may have the same configuration as that of the impedance circuit 48. That is, a variable capacitor 90E and a coil 92E are connected in parallel to each other. The LC parallel circuit having the variable capacitor 90E and the coil 92E is connected in series to one terminal of a fixed capacitor 94E. The other terminal of the fixed capacitor 94E is connected to the ground potential. Further, a connection node N_{E} between the LC parallel circuit (the variable capacitor 90E and the coil 92E) and the fixed capacitor 94E is connected to an output terminal of the DC power supply 54 via an LPF 96E.

A DC voltage outputted from the DC power supply 54 flows through the LPF 96E and the coil 92E and, then, is applied to the peripheral conductor 44 of the electrostatic chuck 38 through the transmission line 58. Meanwhile, a part of the radio frequency power, which is applied to the susceptor 12 from the radio frequency power supply 28 via the power feed rod 34, flows into the transmission line 58 from the peripheral conductor 44 of the electrostatic chuck 38. The RF current, that is, the peripheral RF leakage current MI_{E} flows in the transmission line 58 such that the amount of the current is inversely proportional to the impedance of the impedance circuit 56. The peripheral RF leakage current MI_{E} also flows to the ground from the LC parallel circuit (the variable capacitor 90E and the coil 92E) through the fixed capacitor 94E without flowing into the DC power supply 54. The LPF 96E almost completely blocks the RF leakage current MI_{E} in front of the DC power supply 54. The current sensor 60 measures a current value or current amount of the peripheral RF leakage current MI_{E} flowing in the transmission line 58. The measured value of the RF leakage current is provided to the controller 62. The controller 62 can variably control the impedance position of the variable capacitor 90E via a step motor 98E such that the measured value of the RF leakage current obtained by the current sensor 60 is equal to a set value.

The operations of the central and the peripheral impedance adjusting unit 64 and 66 are explained with reference to FIG. 3. When the radio frequency power is applied to the susceptor 12 from the radio frequency power supply 28 via the power feed rod 34, the RF current flows to an outer surface (main surface) of the susceptor 12 by turning around rear and side surfaces of the susceptor 12 along its surface due to a skin effect. Then, the RF current RFI is discharged to the processing space S from respective parts of the main surface of the susceptor 12 toward the upper electrode 72 or the sidewall of the chamber 10.

Meanwhile, in view of the main surface of the susceptor 12, the central transmission line 45C and the peripheral transmission line 45E, leading to the ground potential respectively from the central conductor 42 and the peripheral conductor 44 of the electrostatic chuck 38, form a third RF current path without passing through the processing space S. Accordingly, a part of the RF current, that is, the central and the peripheral RF leakage current MI_{C} and MI_{E}, flow into the respective transmission lines 45C and 45E from the main surface of the susceptor 12 without being discharged to the processing space S. The current amounts of the central and the peripheral RF leakage current MI_{C} and MI_{E} depend on the impedances of the impedance circuits 48 and 56 in the central and the peripheral impedance adjusting unit 64 and 66, respectively.

In this case, the central RF electron current RFI_{C}, which is discharged from a region of the central conductor 42 on the main surface of the susceptor 12 to the processing space S, is in opposed relationship with the central RF leakage current MI_{C}, which is discharged from the central conductor 42 to the central transmission line 45C. The peripheral RF electron current RFI_{E}, which is discharged from a region of the peripheral conductor 44 on the main surface of the susceptor 12 to the processing space S, is in opposed relationship with the peripheral RF leakage current MI_{E}, which is discharged from the peripheral conductor 44 to the peripheral transmission line 45E. Thus, as the central RF leakage current MI_{C} increases, the central RF electron current RFI_{C} decreases. Further, as the peripheral RF leakage current MI_{E} increases, the peripheral RF electron current RFI_{E} decreases.

As described above, the controller 62 independently and variably controls the impedances of the impedance circuits 48 and 56 via the step motors 98C and 98E, respectively. Accordingly, it is possible to variably control a ratio or balance of the central RF electron current RFI_{C} to the peripheral RF electron current RFI_{E}, as desired, by independently and variably controlling the current amounts of the RF leakage currents MI_{C} and MI_{E}. Therefore, for example, when a mountain-shaped plasma density distribution characteristic with a high plasma density in the central portion as represented by the dotted line PR′ in FIG. 3 is obtained, by reducing the current amount of the peripheral RF leakage current MI_{E} or making it almost zero (without suppressing the peripheral RF electron current RFI_{E}) and by increasing the current amount of the central RF leakage current MI_{C} (by suppressing the central RF electron current RFI_{C}), the electron current density (i.e., plasma density) in the central portion can be locally reduced. Resultantly, the mountain-shaped plasma density distribution characteristic can be rectified into a plasma density distribution characteristic with an almost uniform or flat plasma density as represented by the solid line PR in FIG. 3.

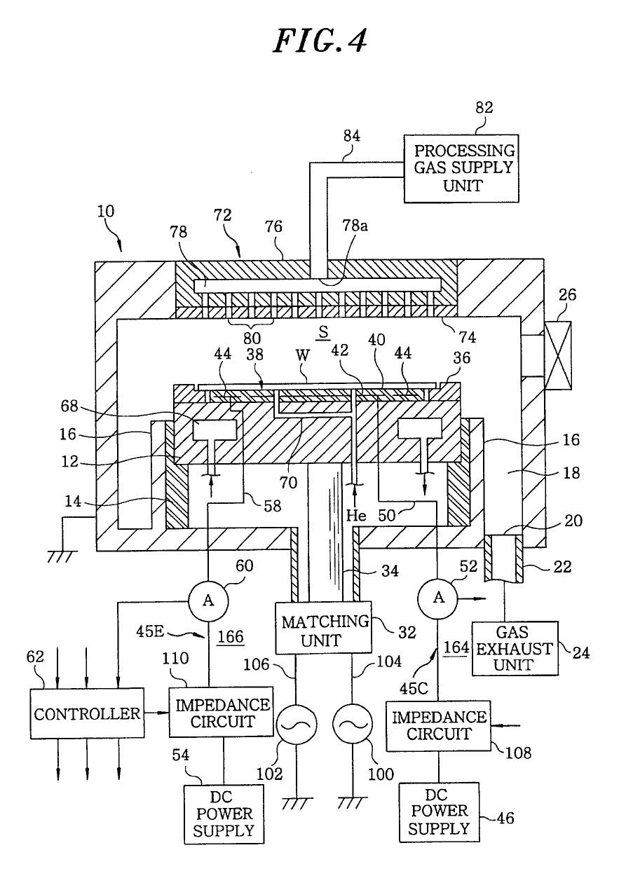

FIG. 4 illustrates a configuration of a plasma processing apparatus in accordance with a second embodiment of the present invention. The plasma processing apparatus is configured as a capacitively coupled plasma etching apparatus of a lower dual frequency application type in which two kinds of radio frequency powers are applied to the lower electrode. Parts having substantially the same configurations and functions as those of the first embodiment will be designated by the same reference numerals in the drawings.

This plasma etching apparatus includes a first radio frequency power supply 100 which outputs a first radio frequency power of a specific frequency, e.g., 60 MHz, appropriate for control of the plasma density, and a second radio frequency power supply 102 which outputs a second radio frequency power of a specific frequency, e.g., 13.56 MHz, appropriate for control of a self-bias voltage generated in the susceptor 12 and energy of ions attracted to the semiconductor wafer W.

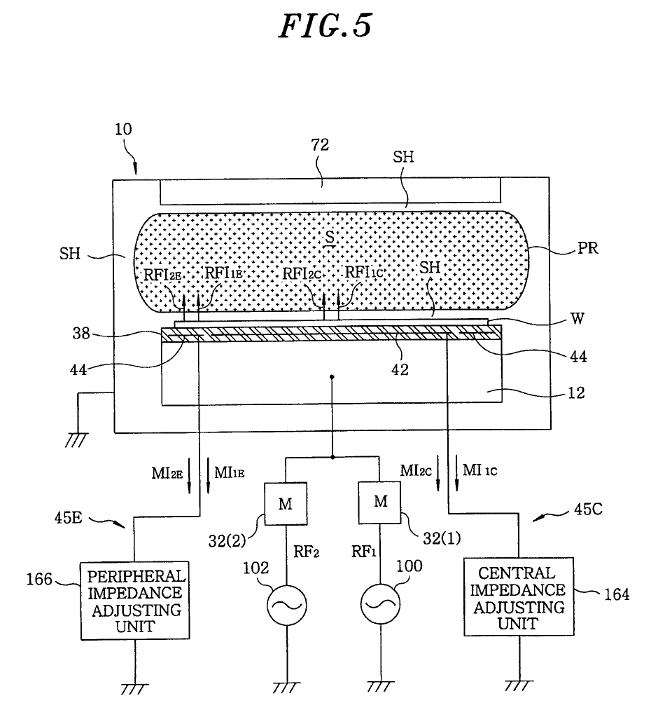

The first radio frequency power RF₁ outputted from the first radio frequency power supply 100 is applied to the susceptor 12 via an RF cable 104, the matching unit 32 and the lower power feed rod 34. The second radio frequency power RF₂ outputted from the second radio frequency power supply 102 is applied to the susceptor 12 via an RF cable 106, the matching unit 32 and the lower power feed rod 34. The matching unit 32 may include a first radio frequency matching circuit 32(1) and a second radio frequency matching circuit 32(2) (FIG. 5).

The operation of the plasma etching apparatus will be explained with reference to FIG. 5. The first and the second radio frequency power RF₁ and RF₂ are dually applied to the susceptor 12 from the first and the second radio frequency power supply 100 and 102. Accordingly, a first and a second RF electron current RFI₁ and RFI₂ are dually discharged to the processing space S from the respective parts of the main surface of the susceptor 12 toward the upper electrode 72 or the sidewall of the chamber 10.

Specifically, a first and a second central RF electron current RFI_{1C} and RFI_{2C} are discharged from the region of the central conductor 42 on the main surface of the susceptor 12. A first and a second peripheral RF electron current RFI_{1E} and RFI_{2E} are discharged from the region of the peripheral conductor 44 on the main surface of the susceptor 12. A plasma PR of the processing gas is generated in the processing space S by a discharge of the RF electron currents, that is, a radio frequency discharge. In this case, the plasma density distribution characteristics in the processing space S in the radial direction of the susceptor are mainly controlled by respective absolute values of the current amount (current density distribution) of the first central RF electron current RFI_{1C} and the current amount (current density distribution) of the first peripheral RF electron current RFI_{1E} and a ratio therebetween.

Further, a space charge layer region of positive ions or a DC electric field region, that is, a sheath SH is formed on the surfaces of the respective parts directly facing the plasma PR in the chamber, particularly, the main surface (outer surface) of the susceptor 12, an outer surface of the upper electrode 72, the sidewall of the chamber 10 and the like. In this case, the sheath width characteristics on the main surface of the susceptor 12 in the radial direction of the susceptor are mainly controlled by respective absolute values of the current amount (current density distribution) of the second central RF electron current RFI_{2C} and the current amount (current density distribution) of the second peripheral RF electron current RFI_{2E} and a ratio thereof. Further, the sheath width at each position on the main surface of the susceptor 12 is proportional to a self-bias voltage at the corresponding position. Accordingly, an increase in the sheath width causes an increase in the energy of ions attracted to the semiconductor wafer W at the corresponding position.

Meanwhile, as in the first embodiment, in view of the main surface of the susceptor 12, the central and the peripheral transmission line 45C and 45E, leading to the ground potential respectively from the central conductor 42 and the peripheral conductor 44 of the electrostatic chuck 38, form a third RF current path without passing through the processing space S. Accordingly, a part of the RF current flows into the transmission lines 45C and 45E from the main surface of the susceptor 12 without being discharged to the processing space S.

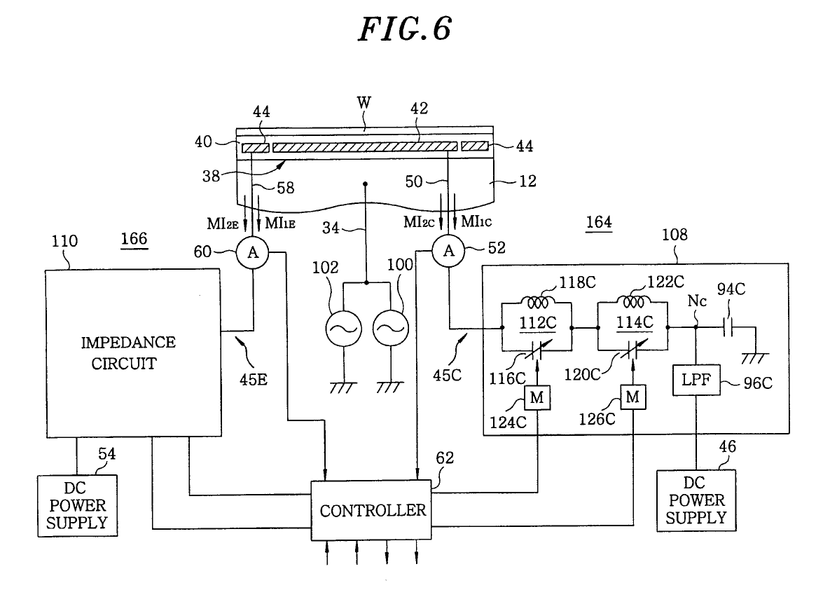

Specifically, a first and a second central RF leakage current MI_{1C} and MI_{2C} corresponding to the first and the second radio frequency power RF₁ and RF₂, respectively, flow into the central transmission line 45C from the central conductor 42. The current amounts of the first and the second central RF leakage current MI_{1C} and MI_{2C} depend on impedances of a first and a second LC parallel circuit 112C and 114C (FIG. 6), to be described later, in a central impedance adjusting unit 164, respectively.

Further, a first and a second peripheral RF leakage current MI_{1E} and MI_{2E} corresponding to the first and the second radio frequency power RF₁ and RF₂, respectively, flow into the peripheral transmission line 45E from the peripheral conductor 44. The current amounts of the first and the second peripheral RF leakage current MI_{1E} and MI_{2E} depend on impedances of a first and a second LC parallel circuit (not shown) in a peripheral impedance adjusting unit 166, respectively.

Further, the first and the second central RF electron current RFI_{1C} and RFI_{2C}, which are discharged from the region of the central conductor 42 on the main surface of the susceptor 12 to the processing space S, are in opposed relationship with the first and the second central RF leakage current MI_{1C} and MI_{2C}, respectively, which are discharged from the central conductor 42 to the central transmission line 45C. The first and the second peripheral RF electron current RFI_{1E} and RFI_{2E}, which are discharged from the region of the peripheral conductor 44 on the main surface of the susceptor 12 to the processing space S, are in opposed relationship with the first and the second peripheral RF leakage current MI_{1E} and MI_{2E}, respectively, which are discharged from the peripheral conductor 44 to the peripheral transmission line 45E. Thus, as the first central RF leakage current MI_{1C} increases, the first central RF electron current RFI_{1C} decreases. Further, as the second central RF leakage current MI_{2C} increases, the second central RF electron current RFI_{2C} decreases. Further, as the first peripheral RF leakage current MI_{1E} increases, the first peripheral RF electron current RFI_{1E} decreases. Further, as the second peripheral RF leakage current MI_{2E} increases, the second peripheral RF electron current RFI_{2E} decreases.

In this case, the central and the peripheral impedance adjusting unit 64 and 66 are configured to independently and variably control the first central RF leakage current MI_{1C}, the second central RF leakage current MI_{2C}, the first peripheral RF leakage current MILE and the second peripheral RF leakage current MI_{2E}, respectively, as will be described later. Accordingly, it is possible to variably control a ratio or balance of the first central RF electron current RFI_{1C} to the first peripheral RF electron current RFI_{1E}, as desired, by variably controlling the current amounts of the first central RF leakage current MI_{1C} and the first peripheral RF leakage current MI_{1E}. Consequently, it is possible to control the plasma density distribution characteristics in the radial direction of the susceptor into a desired profile. Meanwhile, it is possible to variably control a ratio or balance of the second central RF electron current RFI_{2C} to the second peripheral RF electron current RFI_{2E}, as desired, by variably controlling the current amounts of the second central RF leakage current MI_{2C} and the second peripheral RF leakage current MI_{2E}. Consequently, it is possible to control the self-bias voltage characteristics or the ion energy characteristics in the radial direction of the susceptor into a desired profile.

FIG. 6 illustrates exemplary configurations of the central and the peripheral impedance adjusting unit 164 and 166 in accordance with the second embodiment.

An impedance circuit 108 of the central impedance adjusting unit 164 includes the first and the second radio frequency LC circuit 112C and 114C, each having at least one variable reactance element. In the illustrated example, the first radio frequency LC circuit 112C is configured as an LC parallel circuit in which a variable capacitor 116C is connected in parallel to a coil 118C. The second radio frequency LC circuit 114C is configured as an LC parallel circuit in which a variable capacitor 120C is connected in parallel to a coil 122C. The DC voltage outputted from the DC power supply 46 flows through the LPF 96C, the coil 122C and the coil 118C and, then, is applied to the central conductor 42 of the electrostatic chuck 38 through the transmission line 50. The controller 62 may variably control the impedance positions of the variable capacitors 116C and 120C via step motors 124C and 126C, respectively.

In the first radio frequency LC parallel circuit 112C, a capacitance of the variable capacitor 116C and an inductance of the coil 118C are selected to provide a desired impedance to the first central RF leakage current MI_{1C} (60 MHz) and to substantially directly pass the second central RF leakage current MI_{2C} (13.56 MHz) through the coil 118C. Meanwhile, in the second radio frequency LC parallel circuit 114C, a capacitance of the variable capacitor 120C and an inductance of the coil 122C are selected to provide a desired impedance to the second central RF leakage current MI_{2C} (13.56 MHz) and to substantially directly pass the first central RF leakage current MI_{1C} (60 MHz) through the variable capacitor 120C.

Although an impedance circuit 110 of the peripheral impedance adjusting unit 166 is not shown in the drawing, the impedance circuit 110 has the same circuit configuration as that of the impedance circuit 108 of the central impedance adjusting unit 164.

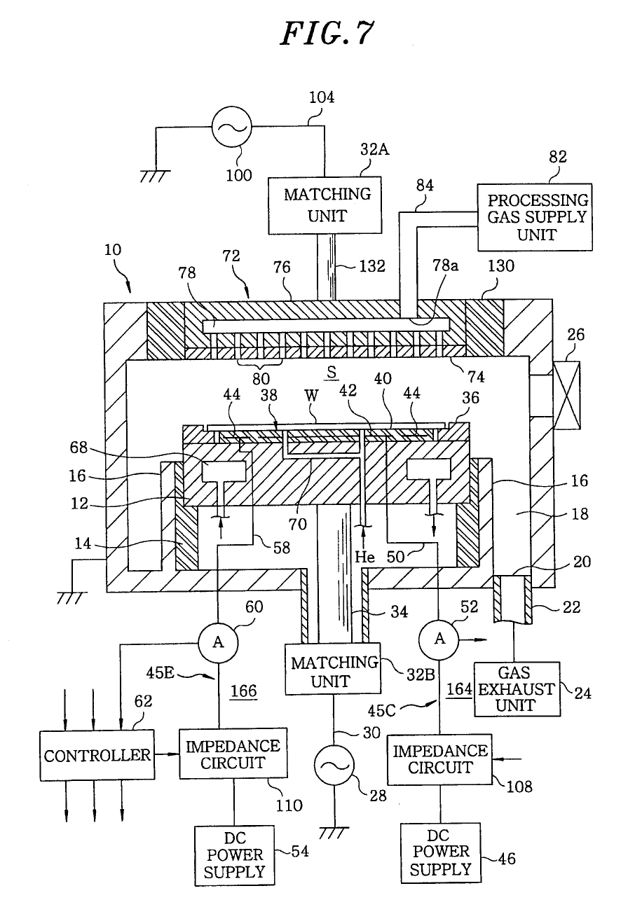

FIG. 7 illustrates a configuration of a plasma processing apparatus in accordance with a third embodiment of the present invention. This plasma processing apparatus is configured as a capacitively coupled plasma etching apparatus of an upper and lower dual frequency application type in which two kinds of radio frequency powers are respectively applied to the upper and the lower electrode. Parts having substantially the same configurations and functions as those of the first and the second embodiment will be designated by the same reference numerals in the drawings.

In this plasma etching apparatus, the upper electrode (shower head) 72 is mounted at the ceiling portion of the chamber 10 through an annular insulator 130 in a non-ground state. A first radio frequency power (e.g., 60 MHz) for plasma generation is applied to the upper electrode 72. Specifically, an output terminal of the first radio frequency power supply 100 is electrically connected to the upper electrode 72 via the RF cable 104, a matching unit 32A and an upper power feed rod 132. Further, a second radio frequency power (e.g., 13.56 MHz) for ion attraction is applied to the susceptor 12. Specifically, an output terminal of the second radio frequency power supply 102 is electrically connected to the susceptor 12 via the RF cable 106, a matching unit 32B and the lower power feed rod 34.

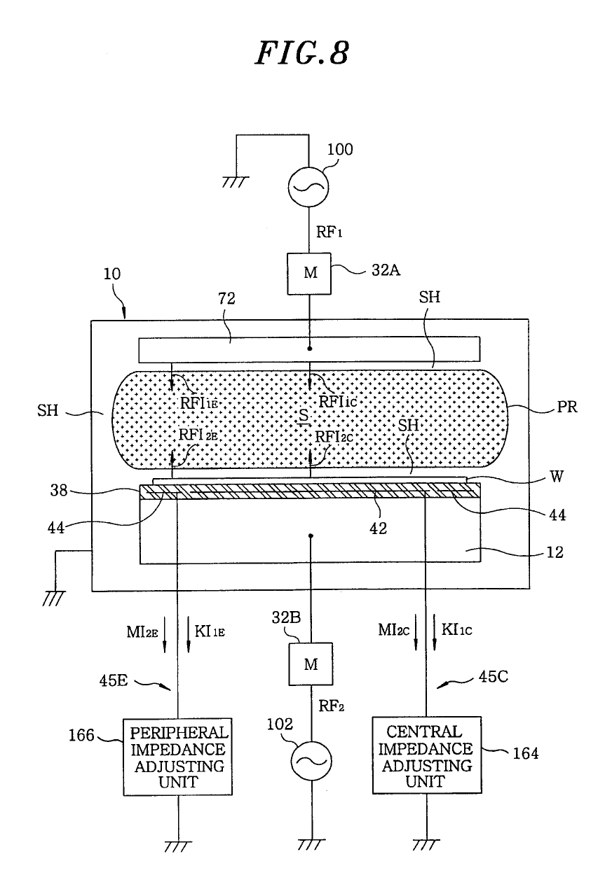

The operation of the plasma etching apparatus will be explained with reference to FIG. 8. The first radio frequency power RF₁ is applied to the upper electrode 72 from the first radio frequency power supply 100. The first RF electron current RFI₁ is discharged to the processing space S from respective parts of a main surface of the upper electrode 72 toward the lower electrode (susceptor) 12 or the sidewall of the chamber 10. Meanwhile, the second radio frequency power RF₂ is applied to the susceptor 12 from the second radio frequency power supply 102. The second RF electron current RFI₂ is discharged to the processing space S from the respective parts of the main surface of the susceptor 12 toward the upper electrode 72 or the sidewall of the chamber 10.

Specifically, the first central RF electron current RFI_{1C} is discharged from an electrode central region of the upper electrode 72 facing the central conductor 42 disposed therebelow. The first peripheral RF electron current RFI_{1E} is discharged from an electrode peripheral region of the upper electrode 72 facing the peripheral conductor 44 disposed therebelow. Meanwhile, the second central RF electron current RFI_{2C} is discharged from the region of the central conductor 42 in the susceptor 12, and the second peripheral RF electron current RFI_{2E} is discharged from the region of the peripheral conductor 44 in the susceptor 12. The plasma PR of the processing gas is generated in the processing space S by the discharges of the RF electron currents, that is, the radio frequency discharges. In this case, the plasma density distribution characteristics in the processing space S in the radial direction of the susceptor 12 are mainly controlled by the respective absolute values of the current amount (current density distribution) of the first central RF electron current RFI_{1C} and the current amount (current density distribution) of the first peripheral RF electron current RFI_{1E} and a ratio therebetween.

Further, a space charge layer region of positive ions or a DC electric field region, that is, a sheath SH is formed on the surfaces of the respective parts directly facing the plasma PR in the chamber, particularly, the main surface (outer surface) of the susceptor 12, the outer surface of the upper electrode 72, the sidewall of the chamber 10 and the like. In this case, the sheath width characteristics on the main surface of the susceptor 12 in the radial direction of the susceptor are mainly controlled by respective absolute values of the current amount (current density distribution) of the second central RF electron current RFI_{2C} and the current amount (current density distribution) of the second peripheral RF electron current RFI_{2E} and a ratio therebetween.

Meanwhile, as in the first and the second embodiment, in view of the main surface of the susceptor 12, the central and the peripheral transmission line 45C and 45E, leading to the ground potential respectively from the central conductor 42 and the peripheral conductor 44 of the electrostatic chuck 38, form a third RF current path without passing through the processing space S. Accordingly, a part of the RF current flows into the transmission lines 45C and 45E from the main surface of the susceptor 12 without being discharged to the processing space S.

Specifically, a first central RF attraction current KI_{1C} corresponding to the first radio frequency power RF₁ and the second central RF leakage current MI_{2C} corresponding to the second radio frequency power RF₂ flow into the central transmission line 45C from the central conductor 42. The current amounts of the first central RF attraction current KI_{1C} and the second central RF leakage current MI_{2C} depend on the impedances of the first and the second LC parallel circuit 112C and 114C (FIG. 6) in the central impedance adjusting unit 164, respectively.

Further, a first peripheral RF attraction current KI_{1E} corresponding to the first radio frequency power RF₁ and the second peripheral RF leakage current MI_{2E} corresponding to the second radio frequency power RF₂ flow into the peripheral transmission line 45E from the peripheral conductor 44. The current amounts of the first peripheral RF attraction current KI_{1E} and the second peripheral RF leakage current MI_{2E} depend on the impedances of the first and the second LC parallel circuit (not shown) in the peripheral impedance adjusting unit 166, respectively.

Further, a vertical downward component of the first central RF electron current RFI_{1C}, which is discharged to the processing space S from the central region of the upper electrode 72, is proportional to the first central RF attraction current KI_{1C}, which flows into the central transmission line 45C from the central conductor 42. Accordingly, as the first central RF attraction current KI_{1C} increases, the vertical downward component of the first central RF electron current RFI_{1C} increases. Further, a vertical downward component of the first peripheral RF electron current RFI_{1E}, which is discharged to the processing space S from the peripheral region of the upper electrode 72, is proportional to the first peripheral RF attraction current KI_{1E}, which flows into the peripheral transmission line 45E from the peripheral conductor 44. Accordingly, as the first peripheral RF attraction current KI_{1E} increases, the vertical downward component of the first peripheral RF electron current RFI_{1E} increases.

Meanwhile, the second central RF electron current RFI_{2C}, which is discharged from the region of the central conductor 42 on the main surface of the susceptor 12 to the processing space S, is in opposed relationship with the second central RF leakage current MI_{2C}, which is discharged from the central conductor 42 to the central transmission line 45C. Accordingly, as the second central RF leakage current MI_{2C} increases, the second central RF electron current RFI_{2C} decreases. Further, the second peripheral RF electron current RFI_{2E}, which is discharged from the region of the peripheral conductor 44 on the main surface of the susceptor 12 to the processing space S, is in opposed relationship with the second peripheral RF leakage current MI_{2E}, which is discharged from the peripheral conductor 44 to the peripheral transmission line 45E. Accordingly, as the second peripheral RF leakage current MI_{2E} increases, the second peripheral RF electron current RFI_{2E} decreases.

In this case, the central and the peripheral impedance adjusting unit 164 and 166 are configured to independently and variably control the first central RF attraction current KI_{1C}, the second central RF leakage current MI_{2C}, the first peripheral RF attraction current KI_{1E} and the second peripheral RF leakage current MI_{2E}, respectively. Accordingly, it is possible to variably control a ratio or balance of the vertical downward component of the first central RF electron current RFI_{1C} to the vertical downward component of the first peripheral RF electron current RFI_{1E}, as desired, by variably controlling the current amounts of the first central RF attraction current KI_{1C} and the first peripheral RF attraction current KI_{1E}. Consequently, it is possible to control the plasma density distribution characteristics in the radial direction of the susceptor 12 into a desired profile. At the same time, it is possible to variably control a ratio or balance of the second central RF electron current RFI_{2C} to the second peripheral RF electron current RFI_{2E}, as desired, by variably controlling the current amounts of the second central RF leakage current MI_{2C} and the second peripheral RF leakage current MI_{2E}. Consequently, it is possible to control the self-bias voltage characteristics or the ion energy characteristics in the radial direction of the susceptor 12 into a desired profile.

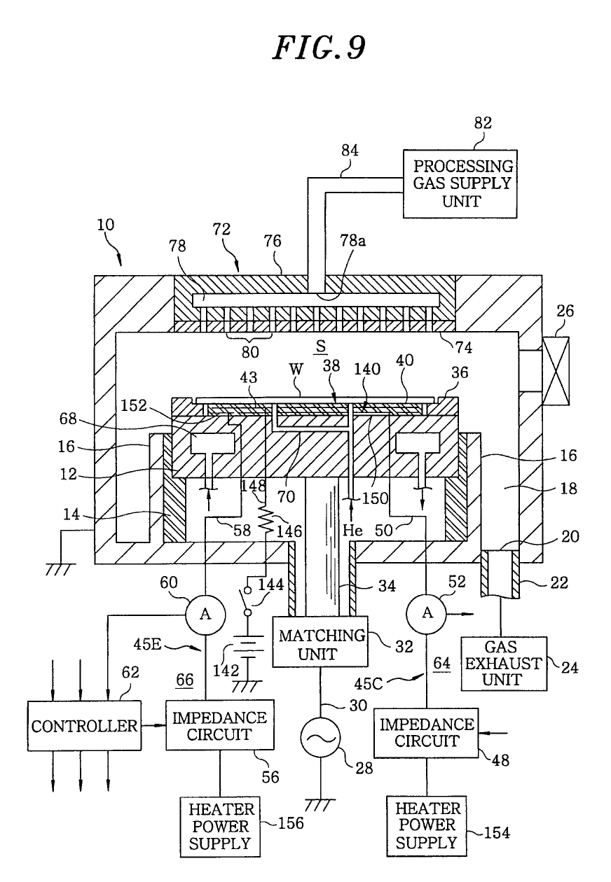

FIG. 9 illustrates a configuration of a plasma processing apparatus in accordance with a fourth embodiment of the present invention. This plasma processing apparatus includes the electrostatic chuck 38 for attractively holding the wafer and a heating element 140 for heating the wafer on the wafer mounting portion of the upper surface of the susceptor 12. The electrostatic chuck 38 includes the film-shaped or plate-shaped dielectric member 40 which is integrally formed or fixed on the upper surface of the susceptor 12. The dielectric member 40 includes a mesh-shaped conductor 43 embedded therein, the conductor 43 being electrically connected to an external DC power supply 142 that is disposed at the outside of the chamber 10 via a switch 144, a high resistance resistor 146 and a DC high voltage line 148. Accordingly, the semiconductor wafer W can be attractively held on the electrostatic chuck 38 by a Coulomb force due to a high DC voltage applied from the DC power supply 142.

The heating element 140 is formed of, for example, a spiral resistance heating wire, which is embedded in the dielectric member 40 together with the conductor 43 of the electrostatic chuck 38. For instance, the heating element 140 is divided into two parts, i.e., an inner central heating wire 150 and an outer peripheral heating wire 152, in the radial direction of the susceptor 12. The central heating wire 150 is electrically connected to a heater power supply 154 via the central transmission line 45C of the central impedance adjusting unit 64. Further, the peripheral heating wire 152 is electrically connected to an additional heater power supply 156 via the peripheral transmission line 45E of the peripheral impedance adjusting unit 66.

The heater power supplies 154 and 156 are, for example, AC output power supplies which perform a switching (ON/OFF) operation at a commercial frequency by using a solid state relay (SSR). The heater power supplies 154 and 156 are connected to the central heating wire 150 and the peripheral heating wire 152 as closed loop circuits, respectively. Accordingly, the central transmission line 45C has a pair of transmission paths forming a reciprocating current passage, each transmission path having the impedance circuit 48. In the same way, the peripheral transmission line 45E has a pair of transmission paths forming a reciprocating current passage, each transmission path having the impedance circuit 56.

In this embodiment, the current outputted from the heater power supply 154 is fed or supplied to the central heating wire 150 via the central transmission line 45C of the central impedance adjusting unit 64 to generate Joule heat at respective parts of the central heating wire 150. Meanwhile, the current outputted from the heater power supply 156 is fed or supplied to the peripheral heating wire 152 via the peripheral transmission line 45E of the peripheral impedance adjusting unit 66 to generate Joule heat at respective parts of the peripheral heating wire 152. Accordingly, cooling of the chiller and heating of the heater are simultaneously provided to the susceptor 12. Further, heating of the heater is independently controlled in the central portion and the edge portion in the radial direction. Accordingly, it is possible to quickly change or increase/decrease the temperature and also to control a profile of a temperature distribution as desired or in various ways.

The central impedance adjusting unit 64 and the peripheral impedance adjusting unit 66 may have the same configuration and obtain the same effect in controlling the plasma density distribution as those of the first embodiment. That is, electrically, the central conductor 42, the peripheral conductor 44, and the DC power supplies 46 and 54 in the first embodiment are merely replaced by the central heating wire 150, the peripheral heating wire 152 and the heater power supplies 154 and 156, respectively. Accordingly, the operations of the central impedance adjusting unit 64 and the peripheral impedance adjusting unit 66 are basically the same as in the first embodiment.

Also in the second and the third embodiment, the above-mentioned susceptor having the heater therein is employed and the above-described variation and replacement may be performed.

While the invention has been shown and described with respect to the preferred embodiments, it will be understood by those skilled in the art that various changes and modifications may be without departing from the scope of the invention.

For example, in the impedance circuits 48, 56, 108 and 110 in the above embodiments, the LC parallel circuits with a variable impedance may be replaced by LC series circuits with a variable impedance. In this case, preferably, the DC power supplies 46 and 54 or the heater power supplies 154 and 156 are connected to the transmission lines 45C and 45E at front ends of the LC series circuits, respectively. Further, a capacitor may be added such that the current is not excessively changed. Further, although the transmission lines 45C and 45E of the central impedance adjusting unit 64 and the peripheral impedance adjusting unit 66 also serve as feeder lines of the DC power supplies 46 and 54 or the heater power supplies 154 and 156 in the above embodiments, the transmission lines 45C and 45E may be used exclusively for controlling an impedance in the above embodiments. Further, feeder lines for another purpose may be made to serve also as the transmission lines 45C and 45E in the above embodiments. Either one of the DC power supplies 46 and 54 may be changed into a coil connected to the ground potential. Further, the apparatus may be configured to include either one of the central impedance adjusting unit 64 and the peripheral impedance adjusting unit 66.

In the electrostatic chuck 38, for example, the conductor for attractively holding the wafer may be divided into three parts, i.e., a central conductor, an intermediate conductor and a peripheral conductor, in the radial direction of the susceptor. In this case, preferably, the central conductor, the intermediate conductor and the peripheral conductor are connected to a central impedance adjusting unit, an intermediate impedance adjusting unit and a peripheral impedance adjusting unit, respectively. In the same way, the conductor for heating may be divided into three parts. Further, the present invention may be applied to a structure in which the electrostatic chuck or the conductor for heating is disposed on the upper electrode.

Further, the present invention may be applied to other plasma processing apparatuses such as a plasma CVD apparatus, a plasma oxidation apparatus, a plasma nitrification apparatus and a sputtering apparatus without being limited to the plasma etching apparatus. Further, the target substrate in the present invention may be various substrates for plat panel display, a photomask, a CD substrate, a printed circuit board and the like without being limited to the semiconductor wafer.

What is claimed is:

1. A plasma processing apparatus, comprising:
an evacuable processing chamber;
a first electrode disposed in the processing chamber and mounted to the processing chamber via an insulating body;
a second electrode disposed in the processing chamber to face the first electrode;
a processing gas supply unit for supplying a desired processing gas to a processing space between the first electrode and the second electrode;
a first radio frequency power supply for applying a first radio frequency power to the first electrode;
a central conductor and a peripheral conductor which are provided in a main surface of the first electrode via an insulating material and are separately disposed at an electrode central portion and an electrode peripheral portion, respectively; and
a first radio frequency leaking unit for leaking the first radio frequency power applied to the first electrode from the first radio frequency power supply through at least one of the central conductor and the peripheral conductor by a desired current amount.

2. The plasma processing apparatus of claim 1, wherein the first radio frequency leaking unit leaks the first radio frequency power to control plasma density distribution characteristics in a radial direction of the first electrode.

3. The plasma processing apparatus of claim 1, wherein the first radio frequency leaking unit comprises a transmission line connected to the central conductor or the peripheral conductor and an impedance adjusting unit which provides a desired impedance to the first radio frequency power in the transmission line.

4. The plasma processing apparatus of claim 3, wherein the impedance adjusting unit comprises a variable impedance circuit provided in the transmission line.

5. The plasma processing apparatus of claim 4, wherein the impedance adjusting unit comprises a radio frequency current measuring unit which measures a current amount of the first radio frequency power flowing in the transmission line, and an impedance controller which variably controls an impedance of the impedance circuit such that the current amount of the first radio frequency power flowing in the transmission line is equal to a desired value.

6. The plasma processing apparatus of claim 1, wherein the first radio frequency leaking unit comprises a central transmission line connected to the central conductor, a central impedance adjusting unit which provides a desired impedance to the first radio frequency power in the central transmission line, a peripheral transmission line connected to the peripheral conductor, and a peripheral impedance adjusting unit which provides a desired impedance to the first radio frequency power in the peripheral transmission line.

7. The plasma processing apparatus of claim 6, wherein the central impedance adjusting unit comprises a central variable impedance circuit provided in the central transmission line, and the peripheral impedance adjusting unit comprises a peripheral variable impedance circuit provided in the peripheral transmission line.

8. The plasma processing apparatus of claim 7, wherein the central impedance adjusting unit comprises a central radio frequency current measuring unit which measures a current amount of the first radio frequency power flowing in the central transmission line, and a central impedance controller which variably controls an impedance of the central impedance circuit such that the current amount of the first radio frequency power flowing in the central transmission line is equal to a desired value, and
wherein the peripheral impedance adjusting unit comprises a peripheral radio frequency current measuring unit which measures a current amount of the first radio frequency power flowing in the peripheral transmission line, and a peripheral impedance controller which variably controls an impedance of the peripheral impedance circuit such that the current amount of the first radio frequency power flowing in the peripheral transmission line is equal to a desired value.

9. The plasma processing apparatus of claim 1, further comprising a second radio frequency power supply for applying a second radio frequency power of a frequency different from that of the first radio frequency power to the first electrode, and a second radio frequency leaking unit for leaking the second radio frequency power applied to the first electrode from the second radio frequency power supply through at least one of the central conductor and the peripheral conductor by a desired current amount.

10. The plasma processing apparatus of claim 9, wherein the first radio frequency power has a frequency appropriate for generating a plasma of the processing gas in the processing space, and the first radio frequency leaking unit leaks the first radio frequency power to control plasma density distribution characteristics in a radial direction of the first electrode, and
wherein the second radio frequency power has a frequency appropriate for controlling a self-bias voltage generated in the first electrode, and the second radio frequency leaking unit leaks the second radio frequency power to control self-bias voltage characteristics in the radial direction of the first electrode.

11. The plasma processing apparatus of claim 9, wherein the first radio frequency leaking unit comprises a first transmission line connected to the central conductor or the peripheral conductor, and a first impedance adjusting unit which provides a desired impedance to the first radio frequency power in the first transmission line, and
wherein the second radio frequency leaking unit comprises a second transmission line connected to the central conductor or the peripheral conductor, and a second impedance adjusting unit which provides a desired impedance to the second radio frequency power in the second transmission line.

12. The plasma processing apparatus of claim 11, wherein the first impedance adjusting unit comprises a first variable impedance circuit provided in the first transmission line, and the second impedance adjusting unit comprises a second variable impedance circuit provided in the second transmission line.

13. The plasma processing apparatus of claim 12, wherein the first impedance adjusting unit comprises a first radio frequency current measuring unit which measures a current amount of the first radio frequency power flowing in the first transmission line, and a first impedance controller which variably controls an impedance of the first impedance circuit such that the current amount of the first radio frequency power flowing in the first transmission line is equal to a desired value, and
wherein the second impedance adjusting unit comprises a second radio frequency current measuring unit which measures a current amount of the second radio frequency power flowing in the second transmission line, and a second impedance controller which variably controls an impedance of the second impedance circuit such that the current amount of the second radio frequency power flowing in the second transmission line is equal to a desired value.

14. The plasma processing apparatus of claim 9, wherein the first radio frequency leaking unit comprises a first central impedance adjusting unit which provides a desired impedance to the first radio frequency power in a central transmission line connected to the central conductor, and a first peripheral impedance adjusting unit which provides a desired impedance to the first radio frequency power in a peripheral transmission line connected to the peripheral conductor, and
wherein the second radio frequency leaking unit comprises a second central impedance adjusting unit which provides a desired impedance to the second radio frequency power in the central transmission line, and a second peripheral impedance adjusting unit which provides a desired impedance to the second radio frequency power in the peripheral transmission line.

15. The plasma processing apparatus of claim 14, wherein the first central impedance adjusting unit comprises a first central variable impedance circuit provided in the central transmission line, and the first peripheral impedance adjusting unit comprises a first peripheral variable impedance circuit provided in the peripheral transmission line, and
wherein the second central impedance adjusting unit comprises a second central variable impedance circuit provided in the central transmission line, and the second peripheral impedance adjusting unit comprises a second peripheral variable impedance circuit provided in the peripheral transmission line.

16. The plasma processing apparatus of claim 15, wherein the first central impedance adjusting unit comprises a first central radio frequency current measuring unit which measures a current amount of the first radio frequency power flowing in the central transmission line; and a first central impedance controller which variably controls an impedance of the first central impedance circuit such that the current amount of the first radio frequency power flowing in the central transmission line is equal to a desired value, and the first peripheral impedance adjusting unit comprises a first peripheral radio frequency current measuring unit which measures a current amount of the first radio frequency power flowing in the peripheral transmission line; and a first peripheral impedance controller which variably controls an impedance of the first peripheral impedance circuit such that the current amount of the first radio frequency power flowing in the peripheral transmission line is equal to a desired value, and
wherein the second central impedance adjusting unit comprises a second central radio frequency current measuring unit which measures a current amount of the second radio frequency power flowing in the central transmission line; and a second central impedance controller which variably controls an impedance of the second central impedance circuit such that the current amount of the second radio frequency power flowing in the central transmission line is equal to a desired value, and the second peripheral impedance adjusting unit comprises a second peripheral radio frequency current measuring unit which measures a current amount of the second radio frequency power flowing in the peripheral transmission line; and a second peripheral impedance controller which variably controls an impedance of the second peripheral impedance circuit such that the current amount of the second radio frequency power flowing in the peripheral transmission line is equal to a desired value.

17. A plasma processing apparatus, comprising:
an evacuable processing chamber;
a first electrode disposed in the processing chamber and mounted to the processing chamber via an insulating body;
a second electrode disposed in the processing chamber to face the first electrode;
a processing gas supply unit for supplying a desired processing gas to a processing space between the first electrode and the second electrode;
a first radio frequency power supply for applying a first radio frequency power to the first electrode;
a second radio frequency power supply for applying a second radio frequency power of a frequency different from that of the first radio frequency power to the second electrode;
a central conductor and a peripheral conductor which are provided in a main surface of the first electrode via an insulating material and are separately disposed at an electrode central portion and an electrode peripheral portion, respectively; and
a radio frequency attracting unit for attracting the second radio frequency power applied to the second electrode from the second radio frequency power supply through at least one of the central conductor and the peripheral conductor by a desired current amount.

18. The plasma processing apparatus of claim 17, wherein the radio frequency attracting unit comprises a transmission line connected to the central conductor or the peripheral conductor and an impedance adjusting unit which provides a desired impedance to the second radio frequency power in the transmission line.

19. The plasma processing apparatus of claim 18, wherein the impedance adjusting unit comprises a variable impedance circuit provided in the transmission line, a radio frequency current measuring unit which measures a current amount of the second radio frequency power flowing in the transmission line, and an impedance controller which variably controls an impedance of the impedance circuit such that the current amount of the second radio frequency power flowing in the transmission line is equal to a desired value.

20. The plasma processing apparatus of claim 17, wherein the radio frequency attracting unit comprises a central transmission line connected to the central conductor, a central impedance adjusting unit which provides a desired impedance to the second radio frequency power in the central transmission line, a peripheral transmission line connected to the peripheral conductor, and a peripheral impedance adjusting unit which provides a desired impedance to the second radio frequency power in the peripheral transmission line.

21. The plasma processing apparatus of claim 20, wherein the central impedance adjusting unit comprises a central variable impedance circuit provided in the central transmission line, a central radio frequency current measuring unit which measures a current amount of the second radio frequency power flowing in the central transmission line, and a central impedance controller which variably controls an impedance of the central impedance circuit such that the current amount of the second radio frequency power flowing in the central transmission line is equal to a desired value.

22. The plasma processing apparatus of claim 20, wherein the peripheral impedance adjusting unit comprises a peripheral variable impedance circuit provided in the peripheral transmission line, a peripheral radio frequency current measuring unit which measures a current amount of the second radio frequency power flowing in the peripheral transmission line, and a peripheral impedance controller which variably controls an impedance of the peripheral impedance circuit such that the current amount of the second radio frequency power flowing in the peripheral transmission line is equal to a desired value.

23. The plasma processing apparatus of claim 17, further comprising a radio frequency leaking unit for leaking the first radio frequency power applied to the first electrode from the first radio frequency power supply through at least one of the central conductor and the peripheral conductor by a desired current amount.

24. The plasma processing apparatus of claim 23, wherein the second radio frequency power has a frequency appropriate for generating a plasma of the processing gas in the processing space, and the radio frequency attracting unit attracts the second radio frequency power to control plasma density distribution characteristics in a radial direction of the first electrode, and
wherein the first radio frequency power has a frequency appropriate for controlling a self-bias voltage generated in the first electrode, and the radio frequency leaking unit leaks the first radio frequency power to control self-bias voltage characteristics in the radial direction of the first electrode.

25. The plasma processing apparatus of claim 23, wherein the radio frequency attracting unit comprises a first transmission line connected to the central conductor or the peripheral conductor, and a first impedance adjusting unit which provides a desired impedance in the first transmission line, and
wherein the radio frequency leaking unit comprises a second transmission line connected to the central conductor or the peripheral conductor, and a second impedance adjusting unit which provides a desired impedance in the second transmission line.

26. The plasma processing apparatus of claim 25, wherein the first impedance adjusting unit comprises a first variable impedance circuit provided in the first transmission line, and the second impedance adjusting unit has a second variable impedance circuit provided in the second transmission line.

27. The plasma processing apparatus of claim 26, wherein the first impedance adjusting unit comprises a first radio frequency current measuring unit which measures a current amount of the second radio frequency power flowing in the first transmission line, and a first impedance controller which variably controls an impedance of the first impedance circuit such that a current amount of the first radio frequency power flowing in the first transmission line is equal to a desired value, and
wherein the second impedance adjusting unit comprises a second radio frequency current measuring unit which measures the current amount of the first radio frequency power flowing in the second transmission line, and a second impedance controller which variably controls an impedance of the second impedance circuit such that the current amount of the second radio frequency power flowing in the second transmission line is equal to a desired value.

28. The plasma processing apparatus of claim 23, wherein the radio frequency attracting unit comprises a first central impedance adjusting unit which provides a desired impedance to the second radio frequency power in a central transmission line connected to the central conductor, and a first peripheral impedance adjusting unit which provides a desired impedance to the second radio frequency power in a peripheral transmission line connected to the peripheral conductor, and
wherein the radio frequency leaking unit comprises a second central impedance adjusting unit which provides a desired impedance to the first radio frequency power in the central transmission line, and a second peripheral impedance adjusting unit which provides a desired impedance to the first radio frequency power in the peripheral transmission line.

29. The plasma processing apparatus of claim 28, wherein the first central impedance adjusting unit comprises a first central variable impedance circuit provided in the central transmission line, and the first peripheral impedance adjusting unit comprises a first peripheral variable impedance circuit provided in the peripheral transmission line, and
wherein the second central impedance adjusting unit comprises a second central variable impedance circuit provided in the central transmission line, and the second peripheral impedance adjusting unit comprises a second peripheral variable impedance circuit provided in the peripheral transmission line.

30. The plasma processing apparatus of claim 29, wherein the first central impedance adjusting unit comprises a first central radio frequency current measuring unit which measures a current amount of the second radio frequency power flowing in the central transmission line; and a first central impedance controller which variably controls an impedance of the first central impedance circuit such that the current amount of the second radio frequency power flowing in the central transmission line is equal to a desired value, and the first peripheral impedance adjusting unit comprises a first peripheral radio frequency current measuring unit which measures a current amount of the second radio frequency power flowing in the peripheral transmission line; and a first peripheral impedance controller which variably controls an impedance of the first peripheral impedance circuit such that the current amount of the second radio frequency power flowing in the peripheral transmission line is equal to a desired value, and
wherein the second central impedance adjusting unit comprises a second central radio frequency current measuring unit which measures a current amount of the first radio frequency power flowing in the central transmission line; and a second central impedance controller which variably controls an impedance of the second central impedance circuit such that the current amount of the first radio frequency power flowing in the central transmission line is equal to a desired value, and the second peripheral impedance adjusting unit comprises a second peripheral radio frequency current measuring unit which measures a current amount of the first radio frequency power flowing in the peripheral transmission line; and a second peripheral impedance controller which variably controls an impedance of the second peripheral impedance circuit such that the current amount of the first radio frequency power flowing in the peripheral transmission line is equal to a desired value.

31. The plasma processing apparatus of claim 1, wherein a substrate to be processed is mounted on the first electrode.

32. The plasma processing apparatus of claim 31, further comprising a DC voltage applying unit for applying a DC voltage to at least one of the central conductor and the peripheral conductor to hold the substrate on the first electrode by an electrostatic attraction force.

33. The plasma processing apparatus of claim 32, further comprising a first DC voltage applying unit for applying a first DC voltage to the central conductor and a second DC voltage applying unit for applying a second DC voltage to the peripheral conductor.

34. The plasma processing apparatus of claim 1, wherein at least one of the central conductor and the peripheral conductor is configured to serve as a resistance heating element to control a temperature of the first electrode, and the plasma processing apparatus further comprises a heater power supply for supplying a power to the resistance heating element.

35. The plasma processing apparatus of claim 34, wherein the central conductor and the peripheral conductor are configured to serve as a first and a second resistance heating element, respectively, and the plasma processing apparatus further comprises a first heater power supply for supplying a power to the first resistance heating element and a second heater power supply for supplying a power to the second resistance heating element.

36. The plasma processing apparatus of claim 11, wherein the first transmission line and the second transmission line are the same transmission line.

37. The plasma processing apparatus of claim 25, wherein the first transmission line and the second transmission line are the same transmission line.
